(19) United States
(12) Patent Application Publication
(10) Pub. No.: US 2015/0364350 A1
(43) Pub. Date: Dec. 17, 2015

(54) HEATING AND COOLING OF SUBSTRATE SUPPORT

(71) Applicant: Applied Materials, Inc., Santa Clara, CA (US)

(72) Inventors: John M. WHITE, Hayward, CA (US); Robin L. TINER, Santa Cruz, CA (US)

(21) Appl. No.: 14/834,324

(22) Filed: Aug. 24, 2015

Related U.S. Application Data
(63) Continuation of application No. 13/238,476, filed on Sep. 21, 2011, now abandoned.
Application No. 13/238,476 is a continuation of application No. 11/776,980, filed on Jul. 12, 2007, now abandoned.
(60) Provisional application No. 60/821,814, filed on Aug. 8, 2006.

(51) Int. Cl. H01L 21/67; C23C 14/22; C23C 16/46

(52) U.S. Cl. CPC H01L 21/67103; C23C 16/463; C23C 16/46; C23C 14/22

(57) ABSTRACT

A process chamber and a method for controlling the temperature of a substrate positioned on a substrate support assembly within the process chamber are provided. The substrate support assembly includes a thermally conductive body, a substrate support surface on the surface of the thermally conductive body and adapted to support a large area substrate thereon, one or more heating elements embedded within the thermally conductive body, and two or more cooling channels embedded within the thermally conductive body to be coplanar with the one or more heating elements. The cooling channels may be branched into two or more equal-length cooling passages being extended from a single point inlet and into a single point outlet to provide equal resistance cooling.

### CROSS-REFERENCE TO RELATED APPLICATIONS

This application is a continuation of co-pending U.S. patent application Ser. No. 13/238,476 (APPM/011429USC01), filed Sep. 21, 2011, which claims benefit of Ser. No. 11/776,980 (APPM/11429), filed Jul. 12, 2007, which claims benefit of U.S. Provisional Patent Application Ser. No. 60/821,814 (APPM/11429L), filed Aug. 8, 2006, which is herein incorporated by reference.

### BACKGROUND OF THE INVENTION

1. Field of the Invention

Embodiments of the invention generally relate to processing of a substrate, and more particularly to a substrate support assembly for regulating the temperature of a substrate in a process chamber. More specifically, the invention relates to methods and apparatus that can be used in, for example, chemical vapor deposition (CVD), physical vapor deposition (PVD), etching, and other substrate processing reactions to deposit, etch, or anneal substrate materials.

2. Description of the Related Art

To deposit a thin film layer onto a substrate, in general, the substrate is supported in a deposition process chamber, and the substrate is heated to a high temperature, such as several hundred degrees centigrade. Gases or chemicals are injected into the process chamber and a chemical and/or physical reaction occurs to deposit a thin film layer onto the substrate. The thin film layer may be a dielectric layer, a semiconductor layer, a metal layer, or any other silicon-containing layer.

The deposition process may be enhanced by a plasma or other thermal sources. For example, the temperature of a substrate in a plasma-enhanced chemical vapor deposition process chamber for processing a semiconductor substrate or a glass substrate can be maintained to a desired high deposition temperature by exposing the substrate to a plasma and/or heating the substrate with heat sources in the process chamber. One example of the heat source includes embedding a heat source or heating element within a substrate support structure, which typically holds the substrate during substrate processing.

During deposition, temperature uniformity across the surface of the substrate is important to ensure the quality of the thin film layer deposited thereon. As the size of the substrate is becoming ever so large, the size of the substrate support structure is required to be larger and many problems arise while heating the substrate to a desired deposition temperature. For example, during deposition of a glass substrate, such as a large area glass substrate for thin film transistor or liquid crystal display fabrication, undesirable warping of the substrate support structure and uneven heating of the substrate can be observed.

In general, achieving temperature uniformity across the surface of the substrate at high deposition temperature may be easier than maintaining substrate temperature at an intermediate deposition temperature when the effect of a few degrees of temperature differential is more dramatic at the intermediate deposition temperature range. For example, 5° C. of temperature variation across the substrate surface will affect the quality of the deposited thin film layer that requires a deposition temperature of 150° C. more significantly as compared to a thin film layer that requires a deposition temperature of 400° C.

Therefore, there is a need for an improved substrate support that improves temperature uniformity across the surface of a substrate inside a process chamber.

### SUMMARY OF THE INVENTION

Embodiments of the invention provide a process chamber with an improved substrate support assembly for regulating the temperature of a substrate during substrate processing. In one embodiment, a substrate support assembly for supporting a large area substrate inside a process chamber is provided. The substrate support assembly includes a thermally conductive body, a substrate support surface on the surface of the thermally conductive body and adapted to support the large area substrate thereon, one or more heating elements embedded within the thermally conductive body, and two or more cooling channels embedded within the thermally conductive body to be coplanar with the one or more heating elements.

Another embodiment of the invention provides a substrate support assembly adapted to support a large area substrate inside a process chamber. The substrate support assembly includes a thermally conductive body, a substrate support surface on the surface of the thermally conductive body and adapted to support the large area substrate thereon, one or more heating elements embedded within the thermally conductive body, and two or more branched cooling passages adapted to be embedded within the thermally conductive body at equal total length (L₁=L₂ . . . =L_{N}).

In another embodiment, a substrate support assembly adapted to support a large area substrate inside a process chamber may include a thermally conductive body, a substrate support surface on the surface of the thermally conductive body and adapted to support the large area substrate thereon, and one or more channels embedded within the thermally conductive body and adapted to flow a fluid therein at a desired temperature set point for heating and/or cooling the substrate support surface. In this embodiment, the one or more cooling/heating channels embedded within the thermally conductive body may be at various different lengths to cover heating and/or cooling of the whole area of the substrate support surface.

In another embodiment, an apparatus for processing a substrate is provided. The apparatus includes a process chamber, a substrate support assembly disposed in the process chamber and adapted to support the substrate thereon, and a gas distribution plate assembly disposed in the process chamber to deliver one or more process gases above the substrate support assembly.

In still another embodiment, a method is provided for maintaining the temperature of a large area substrate inside a process chamber. The method includes preparing the large area substrate on a substrate support surface of a substrate support assembly of the process chamber, flowing a cooling fluid inside the two or more cooling channels, adjusting a first power source for the one or more heating elements and a second power source for the two or more cooling channels, and maintaining the temperature of the large area substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional schematic view of an illustrative process chamber having one embodiment of a substrate support assembly of the invention.

FIG. 2A depicts a horizontal sectional top view of a substrate support assembly according to one embodiment of the invention.

FIG. 2B depicts a horizontal sectional top view of a substrate support assembly according to one embodiment of the invention.

FIG. 3A depicts a horizontal sectional top view of one embodiment of a substrate support assembly of the invention.

FIG. 3B depicts a horizontal sectional top view of another embodiment of a substrate support assembly of the invention.

FIG. 3C depicts a horizontal sectional top view of another embodiment of a substrate support assembly of the invention.

FIG. 3D depicts a horizontal sectional top view of another embodiment of a substrate support assembly of the invention.

FIG. 3E depicts a horizontal sectional top view of another embodiment of a substrate support assembly of the invention.

FIG. 3F depicts a horizontal sectional top view of a substrate support assembly according to one embodiment of the invention

FIG. 4 depicts a cross-sectional schematic view of a substrate support assembly according to one embodiment of the invention.

FIG. 5A is a flow diagram of one embodiment of a method for controlling the temperature of a substrate within a process chamber according to one embodiment of the invention.

FIG. 5B illustrates various combinations to turn the power sources of the heating elements and the power sources of the cooling channels on and off for controlling the temperature of a substrate within a process chamber according to one embodiment of the invention.

FIG. 6A depicts an exemplary cross-sectional schematic view of a bottom gate thin film transistor structure in accordance with one embodiment of the invention.

FIG. 6B depicts an exemplary cross-sectional schematic view of a thin film solar cell structure in accordance with one embodiment of the invention.

### DETAILED DESCRIPTION

Embodiments of the invention generally provide a substrate support assembly for providing uniform heating and cooling within a process chamber. For example, embodiments of the invention may be used to process solar cells. The inventors have found that it is critical to control the temperature of a substrate during deposition and formation of microcrystalline silicon over the substrate in the formation of solar cells since deviation from a desired temperature greatly effects film properties. This problem is made more difficult with thick substrate since the thickness of the substrate also affects thermal regulation of the substrate temperature. Some substrate materials, e.g., substrates for solar cells, are intrinsically thicker than the conventional substrate materials and substrate temperature regulation is much difficult to achieve. It takes a much longer time to heat a thicker substrate to a desired deposition temperature and, once the substrate is heated to a high temperature, it takes a longer time to cool a thicker substrate. As a result, substrate processing throughput inside a process temperature is drastically affected. Pre-heating the substrate may be used to increase the throughput of substrate processing. However, when plasma is used to enhanced deposition of a glass substrate, such as a large area glass substrate for thin film solar cell fabrication that may be thicker and larger in sizes than other glass substrates, the substrate temperature has to be carefully regulated inside the process chamber. The presence of plasma may undesirably increase the temperature of the already pre-heated substrate above a set deposition temperature. Thus, efficient temperature control of the substrate is required.

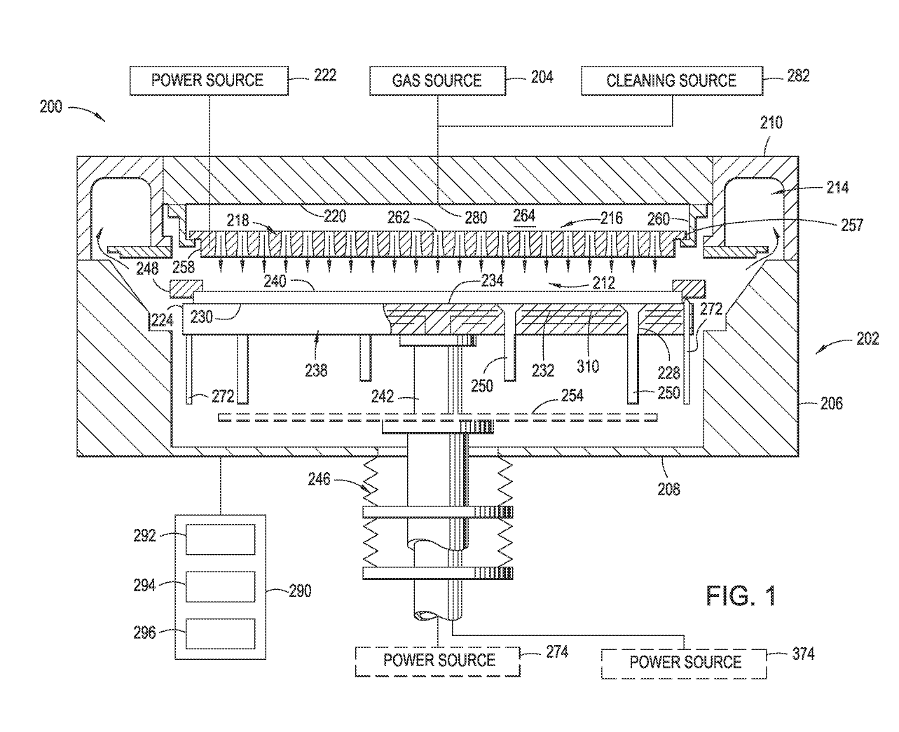

FIG. 1 is a cross-sectional schematic view of one embodiment of a system 200. The invention is illustratively described below in reference to a chemical vapor deposition system configured to process large area substrates, such as a plasma enhanced chemical vapor deposition (PECVD) system, available from AKT, a division of Applied Materials, Inc., Santa Clara, Calif. However, it should be understood that the invention has utility in other system configurations such as etch systems, other chemical vapor deposition systems and any other systems in which regulation of substrate temperature within a chamber is desired, including those systems configured to process circular substrates. It is contemplated that other process chambers, including those from other manufactures, may be utilized to practice the present invention.

The system 200 generally includes a process chamber 202 coupled to a gas source 204 for delivery of one or more source compounds and/or precursors, e.g., a silicon-containing compound supply source, a oxygen-containing compound supply source, a nitrogen-containing compound supply source, a hydrogen gas supply source, a carbon-containing compound supply source, among others, and/or combinations thereof. The process chamber 202 has walls 206 and a bottom 208 that partially define a process volume 212. The process volume 212 is typically accessed through a port and a valve (not shown) in a wall 206 that facilitates movement of a substrate 240 into and out of the process chamber 202. The walls 206 support a lid assembly 210 that contains a pumping plenum 214 that couples the process volume 212 to an exhaust port (that includes various pumping components, not shown) from exhausting any gases and processing by-products out of the process chamber 202.

The lid assembly 210 typically includes an entry port 280 through which process gases provided by the gas source 204 are introduced into the process chamber 202. The entry port 280 is also coupled to a cleaning source 282 to provide a cleaning agent, such as disassociated fluorine, into the process chamber 202 to remove deposition by-products and films from the gas distribution plate assembly 218.

The gas distribution plate assembly 218 is coupled to an interior side 220 of the lid assembly 210. The gas distribution plate assembly 218 is typically configured to substantially follow the profile of the substrate 240, for example, polygonal for large area glass substrates and circular for wafers. The gas distribution plate assembly 218 includes a perforated area 216 through which process precursors and other gases supplied from the gas source 204 are delivered to the process volume 212. The perforated area 216 of the gas distribution plate assembly 218 is configured to provide uniform distribution of gases passing through the gas distribution plate assembly 218 into the process chamber 202. The gas distribution plate assembly 218 typically includes a diffuser plate 258 suspended from a hanger plate 260. A plurality of gas passages 262 are formed through the diffuser plate 258 to allow a predetermined distribution of gas passing through the gas distribution plate assembly 218 and into the process volume 212. The diffuser plate 258 could be circular for semiconductor wafer manufacturing or polygonal, such as rectangular, for manufacturing a glass substrate, such as substrates for flat panel displays, OLED, and solar cells, among others.

The diffuser plate 258 may be positioned above the substrate 240 and suspended vertically by a diffuser gravitational support. In one embodiment, the diffuser plate 258 is supported from the hanger plate 260 of the lid assembly 210 through a flexible suspension 257. The flexible suspension 257 is adapted to support the diffuser plate 258 from its edges to allow expansion and contraction of the diffuser plate 258. The flexible suspension 257 may have different configuration utilized to facilitate the expansion and contraction of the diffuser plate 258. One example of the flexible suspension 257 is disclosed in detail by U.S. Pat. No. 6,477,980, which issued Nov. 12, 2002 with the title “Flexibly Suspended Gas Distribution Manifold for A Plasma Chamber” and is herein incorporated by reference.

The hanger plate 260 maintains the diffuser plate 258 and the interior side 220 of the lid assembly 210 in a spaced-apart relation, thus defining a plenum 264 therebetween. The plenum 264 allows gases flowing through the lid assembly 210 to uniformly distribute across the width of the diffuser plate 258 so that gas is provided uniformly above the center perforated area 216 and flows with a uniform distribution through the gas passages 262.

A substrate support assembly 238 is centrally disposed within the process chamber 202. The substrate support assembly 238 supports the substrate 240, such as a glass substrate and others, during processing. The substrate support assembly 238 generally is grounded such that RF power supplied by a power source 222 to a gas distribution plate assembly 218 positioned between the lid assembly 210 and substrate support assembly 238 (or other electrode positioned within or near the lid assembly of the chamber) may excite gases present in the process volume 212 between the substrate support assembly 238 and the gas distribution plate assembly 218.

The RF power from the power source 222 is generally selected commensurate with the size of the substrate to enhance the chemical vapor deposition process. In one embodiment, a RF power of about 400 W or larger, such as between about 2,000 W to about 4,000 W or between about 10,000 W to about 20,000 W, can be applied to the power source 122 to generate an electric field in the process volume 140. For example, a power density of about 0.2 watts/cm² or larger, such as between about 0.2 watts/cm² to about 0.8 watt/cm², or about 0.45 watts/cm², can be used to be compatible with a low temperature substrate deposition method of the invention. The power source 122 and matching network (not shown) create and sustain a plasma of the process gases from the precursor gases in the process volume 140. Preferably high frequency RF power of 13.56 MHz can be used, but this is not critical and lower frequencies can also be used. Further, the walls of the chamber can be protected by covering with a ceramic material or anodized aluminum material.

The system 200 may also include a controller 290 adapted to execute a software-controlled substrate processing method as described herein. The controller 290 is included to interface with and control the functions of various components of the system 200, such as the power supplies, lift motors, heating sources, flow controllers for gas injection and cooling fluid injection, vacuum pumps, and other associated chamber and/or processing functions. The controller 290 typically includes a central processing unit (CPU) 294, support circuits 296 and a memory 292. The CPU 294 may be one of any form of computer processor that can be used in an industrial setting for controlling various chambers, apparatuses, and chamber peripherals.

The controller 290 executes system control software stored in the memory, 292, which may be a hard disk drive, and can include analog and digital input/output boards, interface boards, and stepper motor controller boards. Optical and/or magnetic sensors are generally used to move and determine the position of movable mechanical assemblies. The memory 292, any software, or any computer-readable medium coupled to the CPU 294 may be one or more readily available memory devices, such as random access memory (RAM), read only memory (ROM), hard disk, CD, floppy disk, or any other form of digital storage, for local or remote for memory storage. The support circuits 296 are coupled to the CPU 294 for supporting the CPU 294 in a conventional manner. These circuits include cache, power supplies, clock circuits, input/output circuitry, subsystems, and the like.

The controller 290 may be used to control the temperature of the substrate disposed on the system, including any deposition temperature, heating of the substrate support, and/or cooling of the substrates. The controller 290 is also used to control processing/deposition time performed by the process chamber 202, the timing for striking a plasma, maintaining temperature control within the process chamber, etc.

### Substrate Support Assembly of a Process Chamber

The substrate support assembly 238 is coupled to a shaft 242 and connected to a lift system (not shown) for moving the substrate support assembly 238 between an elevated processing position (as shown) and a lowered substrate transfer position. The shaft 242 additionally provides a conduit for electrical and thermocouple leads between the substrate support assembly 238 and other components of the process chamber 202. A bellows 246 is coupled to the substrate support assembly 238 to provide a vacuum seal between the process volume 212 and the atmosphere outside the process chamber 202 and facilitate vertical movement of the substrate support assembly 238.

The lift system of the substrate support assembly 238 is generally adjusted such that spacing between the substrate 240 and the gas distribution plate assembly 218 is optimized, such as at about 400 mils or larger, during processing. The ability to adjust the spacing enables the process to be optimized over a wide range of deposition conditions, while maintaining the required film uniformity over the area of a large substrate. Substrate support assemblies that may be adapted to benefit from the invention are described in commonly assigned U.S. Pat. No. 5,844,205, issued Dec. 1, 1998 to White et al.; U.S. Pat. No. 6,035,101, issued Mar. 7, 2000 to Sajoto et al., all of which are hereby incorporated by reference in their entireties.

The substrate support assembly 238 includes a conductive body 224 having a substrate support surface 234 to support the substrate 240 thereon within the process volume 212 during substrate processing. The conductive body 224 can be made of a metal or metal alloy material which provides thermal conductivity. In one embodiment, the conductive body 224 is made of an aluminum material. However, other suitable materials can also be used.

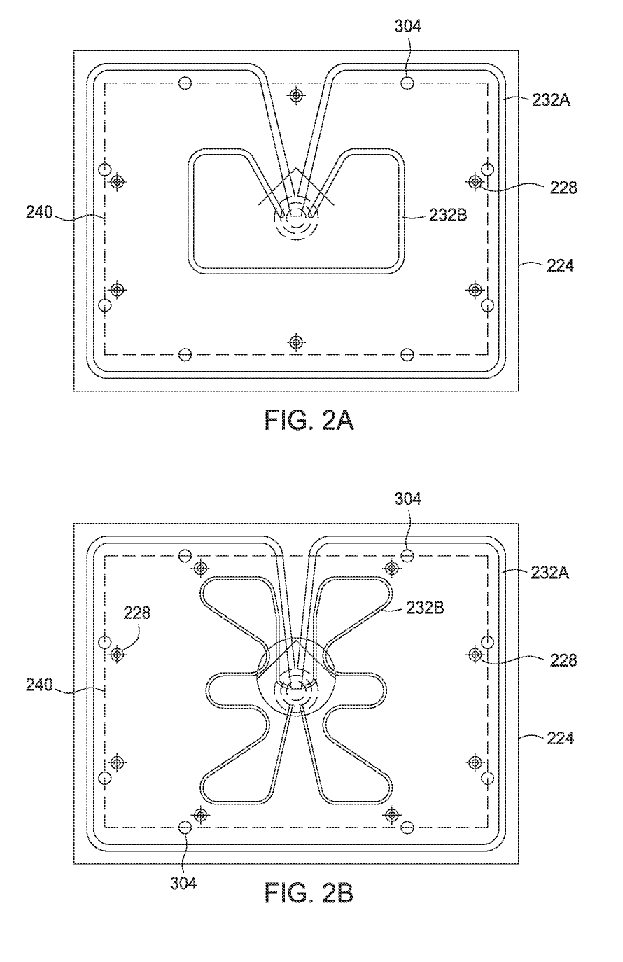

The substrate support assembly 238 additionally supports a shadow frame 248 circumscribing the substrate 240 disposed on the substrate support surface 234 during substrate processing. Generally, the shadow frame 248 prevents deposition at the edges of the substrate 240 and the substrate support assembly 238 and the substrate 240 does not stick to the substrate support assembly 238. The shadow frame 248 is generally positioned alongside inner wall of the chamber body when the substrate support assembly 238 is in a lower non-processing position (not shown). The shadow frame 248 can be engaged and aligned to the conductive body 224 of the substrate support assembly 238, when the substrate support assembly 238 is in an upper processing position, as shown in FIG. 1, by matching one or more alignment grooves on the shadow frame 248 with one or more alignment pins 272. The one or more alignment pins 272 are adapted to pass through one or more alignment pin holes 304 (shown in FIGS. 2A, 2B) located on and near the perimeter of the conductive body 224. The one or more alignment pins 272 may be optionally supported by a support pin plate 254 to be movable with the conductive body 224 during substrate loading and unloading

The substrate support assembly 238 has a plurality of substrate support pin holes 228 disposed therethrough that accept a plurality of substrate support pins 250. The substrate support pins 250 are typically comprised of ceramic or anodized aluminum. The substrate support pins 250 may be actuated relative to the substrate support assembly 238 by the support pin plate 254 to project from the support surface 230, thereby placing the substrate in a spaced-apart relation to the substrate support assembly 238. Alternatively, there may not be a lift plate and the substrate support pins 250 can be projected by the bottom 208 of the process chamber 202 when the substrate support assembly 238 is lowered in position.

The substrate support assembly 238 which is temperature controlled may also include one or more electrodes and/or heating elements 232 coupled to one or more power sources 274 to controllably heat the substrate support assembly 238 and the substrate 240 positioned thereon to a predetermined temperature range. Typically, in a CVD process, the one or more heating elements 232 maintain the substrate 240 at an uniform temperature of at least higher than room temperature, such as about 60 degrees Celsius or higher, typically at a temperature of about between about 80 degrees to at least about 460 degrees Celsius, depending on the deposition processing parameters for the material being deposited on the substrate. In one embodiment, the one or more heating elements 232 are embedded within the conductive body 224.

FIGS. 2A-2B illustrate planar views of the one or more heating elements 232 disposed across the dimension of the conductive body 224. In one embodiment, the heating element 232 may include an outer heating elements 232A and an inner heating element 232B provided to run along inner and outer grooved regions of the substrate support assembly 238. The outer heating elements 232A may enter the conductive body 224 through the shaft 242, loop around an outer perimeter of the conductive body 224 in one or more outer loops, and exit through the shaft 242. Similarly, the inner heating element 232B may enter the conductive body 224 through the shaft 242, loop around a center region of the conductive body 224 in one or more inner loops, and exit through the shaft 242.

As shown in FIGS. 2A and 2B, the inner heating element 232B and the outer heating element 232A may be identical in construction, and only differ in length and positioning about the portion of the substrate support assembly 238. The inner heating element 232B and the outer heating element 232A may be manufactured inside the substrate support assembly to form into one or more heating element tubes at the appropriate ends to be disposed within the hollow core of the shaft 242. Each heating element and heating element tube may include a conductor lead wire or a heater coil embedded therein. In addition, other heating elements, heater lines patterns or configurations can also be used. For example, the one or more heating elements 232 can also be positioned on the back side of the conductive body 224 or clamped onto the conductive body 224 by a clamp plate. The one or more heating elements 232 may be resistively heated or by other heating means to a predetermined temperature of about 80° C. or higher.

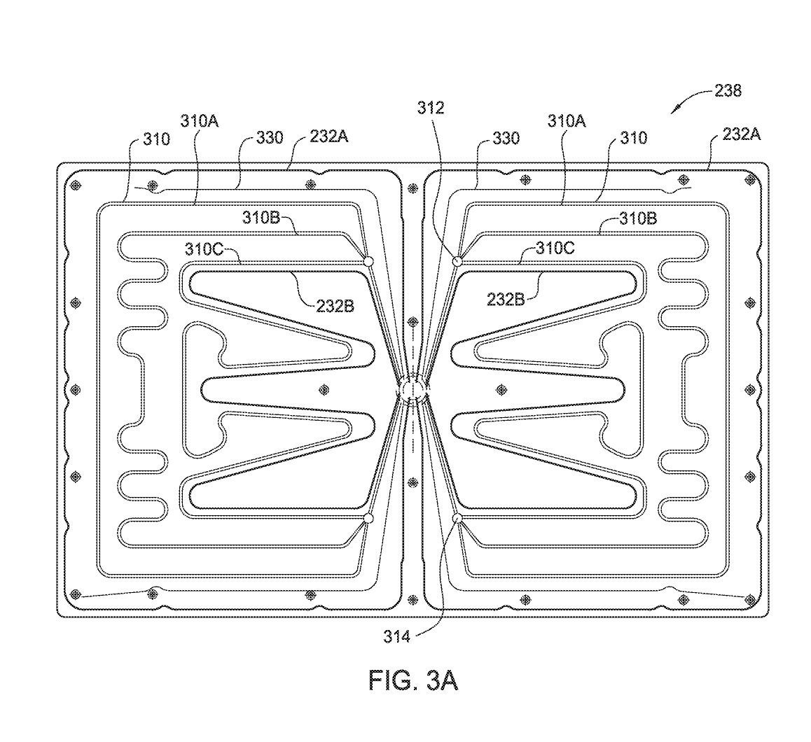

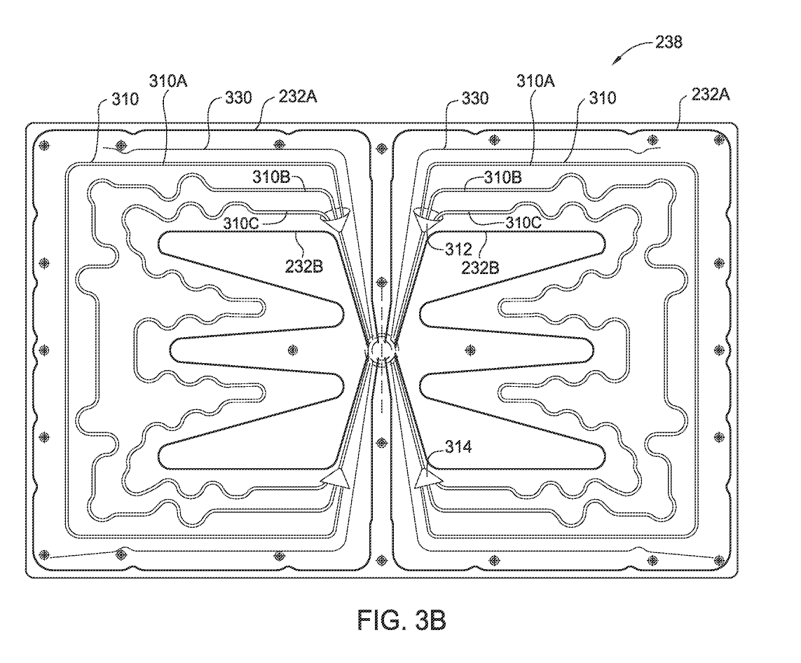

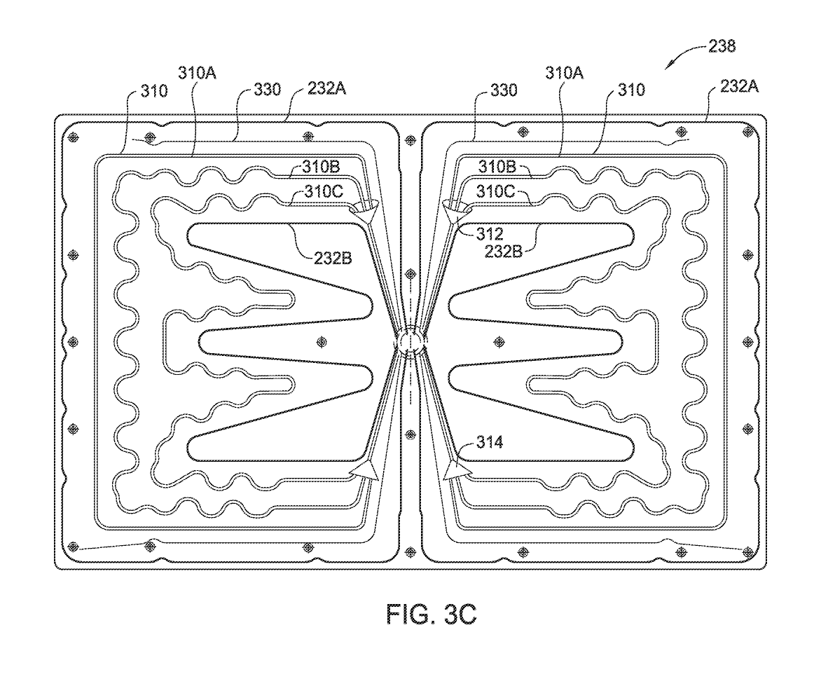

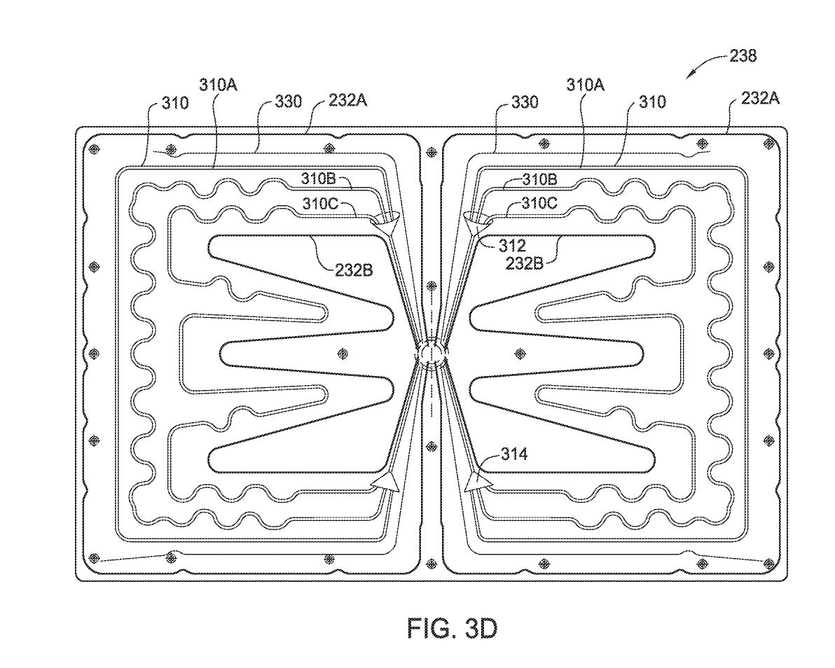

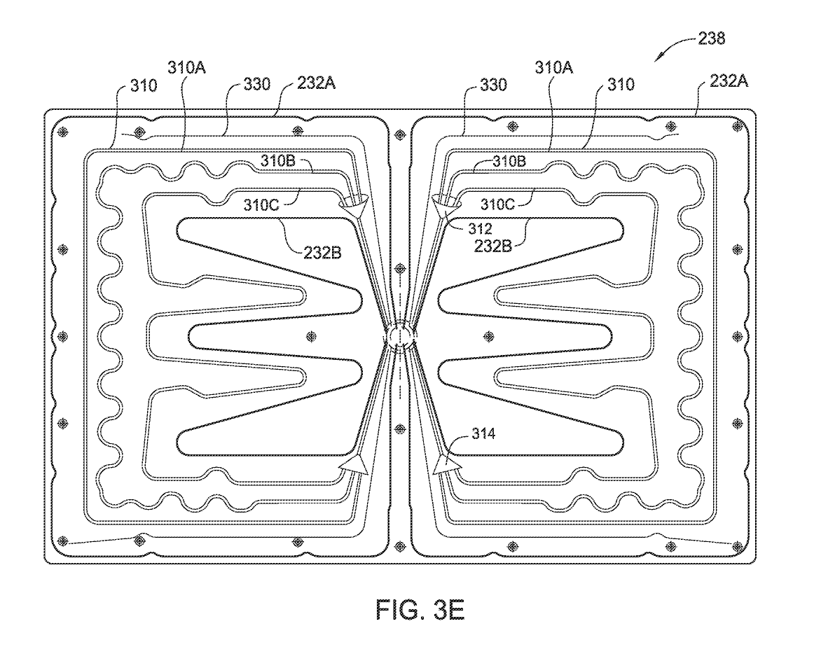

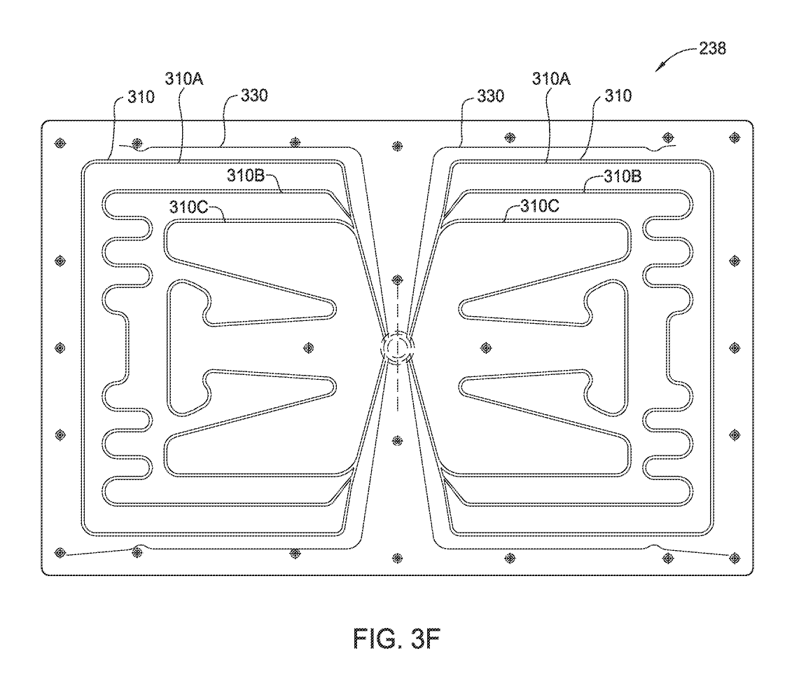

In addition, the routing of the inner heating element 232B and the outer heating element 232A in the conductive body 224 can be in dual loops that are somewhat generally parallel, as shown in FIG. 2A. Alternatively, the inner heating element 232B can be in leaflet-like loops to somewhat evenly cover the surface of the plate-like structure, as shown in FIG. 2B. This dual loop pattern provides for a generally axially-symmetric temperature distribution across the conductive body 224, while allowing for greater heat losses at the edges of the surfaces. In general, one or more thermocouples 330 (shown in FIGS. 3A-3F) can be used within the substrate support assembly 238. In one embodiment, two thermocouples are used, such as one for the center region and one for the outer perimeter of the conductive body 224. In another embodiment, four thermocouples, extending from the center of the conductive body 224 to its four corners are used.

The conductive body 224 for display applications may be in square or rectangular shape, as shown herein. Exemplary dimensions of the substrate support assembly 238 to support the substrate 240, such as a glass panel, may include a width of about 30 inches and a length of about 36 inches. However, the size of the plate-like structure of the invention is not limiting and the invention encompasses other shapes, such as round or polygonal. In one embodiment, the conductive body 224 is rectangular in shape having a width of about 26.26 inches and a length of about 32.26 inches or larger, which allows for the processing of a glass substrate for flat panel displays up to about 570 mm by 720 mm or larger in size. In another embodiment, the conductive body 224 is rectangular in shape having a width of, for example, from about 80 inches to 100 inches and a length of, for example, from about 80 inches to about 120 inches. As an example, a rectangular conductive body of about 95 inches wide by about 108 inches long can be used for processing of a glass substrate, for example about 2200 mm by 2600 mm or larger in size. In one embodiment, the conductive body 224 is conformal to the shape of the substrate 240 and may be larger in dimension to surround the area of the substrate 240. In another embodiment, the conductive body 224 may be slightly smaller in dimension and size, and yet conformal to the shape of the substrate 240.

The substrate support assembly 238 may include additional mechanisms adapted to retain and align the substrate 240. For example, the conductive body 224 may include one or more substrate support pin holes 228 for a plurality of substrate support pins 250 therethrough and adapted to support the substrate 240 a small distance above the conductive body 224. The substrate support pins 250 can be positioned near the perimeter of the substrate 240 to facilitate the placement or removal of the substrate 240 by a transfer robot or other transfer mechanism disposed exterior to the process chamber 202 without interfering with the transfer robot. In one embodiment, the substrate support pins 250 can be made of an insulating material, such as ceramic materials, anodized aluminum oxides materials, among others, to provide electrical insulation during substrate processing and still being thermally conductive. The substrate support pins 250 may be optionally supported by the support pin plate 254 such that the substrate support pins 250 are movable within the substrate support assembly 238 for lifting the substrate 240 during substrate loading and unloading. Alternatively, the substrate support pins 250 may be secured to the chamber bottom and the conductive body 224 is vertically movable for the substrate support pins 250 to pass through.

In another embodiment, at least one outer loop of the heating element 232B or the outer heating element 232A is configured to align to an outer perimeter of the substrate 240 when the substrate 240 is placed onto the substrate support surface 234 of the conductive body 224. For example, when the dimension of the conductive body 224 is larger than the dimension of the substrate 240, the position of the outer heating element 232A may be configured to enclose the perimeter of the substrate 240 without interfering with the positions of one or more pin holes on the conductive body 224, e.g., the substrate support pin holes 250 or the alignment pin holes 304.

As shown in FIGS. 2A and 2B, one embodiment of the invention provides that the outer heating element 232A is positioned around the one or more substrate support pin holes 228 and farther away from the center of the conductive body 224 without interfering with the positions of the one or more substrate support pin holes 228, thus, the positions of the substrate support pins 250 for supporting the edges of the substrate 240. Further, another embodiment of the invention provides that the outer heating element 232A is positioned between the one or more substrate support pin holes 228 and the outer edges of the conductive body 224 in order to provide heating to the edges and perimeter of the substrate 240.

### Cooling Structure of the Substrate Support Assembly

As mentioned earlier, problems arise during substrate processing of large area substrates to regulate and maintain the temperature of the large area substrates. Accordingly, additional substrate cooling of the substrate in addition to heating may be required in order to achieve uniform substrate temperature profiles. According to one or more aspects of the invention, the substrate support assembly 238 may further includes a cooling structure 310 embedded within the conductive body 224.

FIGS. 3A-3F illustrate exemplary configurations of the cooling structure 310 in the conductive body 224 of the substrate support assembly 238. The cooling structure 310 includes one or more cooling channels configured to maintain temperature control and compensate temperature variation which may occur during substrate processing, such as a temperature increase or spike when a RF plasma is generated inside the process chamber 202. For example, there may be one cooling channel configured for cooling of the left side of the substrate 240 and another cooling channel configured for cooling of the right side of the substrate. The cooling structure 310 can be coupled to one or more power sources 374 and is constructed to efficiently regulate the temperature of the substrate during substrate processing.

In one embodiment, the cooling channels are embedded within the conductive body 224 and configured to be coplanar with the one or more heating elements. In another embodiment, each of the cooling channels may be branched into two or more cooling passages. For example, as shown in FIGS. 3A-3F, each of the cooling channels may include cooling passages 310A, 310B, 310C adapted to cover cooling of the whole area of the substrate support surface 234. In addition, the cooling passages 310A, 310B, 310C embedded within the thermally conductive body may be coplanar with each other. Furthermore, the cooling passages 310A, 310B, 310C may be manufactured to be about the vicinity of the same plane with the heating elements 232A, 232B.

The shape of the cooling passages 310A, 310B, 310C can be adapted to be varied, as exemplarily shown in FIG. 3A-3F. Overall, the cooling passages 310A, 310B, 310C may be configured in spiral, looped, curvy, serpentine, and/or straight line configurations. For example, the cooling passages 310A may be closer to the outer heating element and the cooling passage 310C may be closer to the inner heating element in curvy shape, whereas the cooling passage 310B may be shaped in loops in between the cooling passage 310A and the cooling passage 310B.

In one embodiment, the cooling passages 310A, 310B, 310C can be extended from a single point inlet, e.g., an inlet 312, and into a single point outlet, e.g., an outlet 314, so as to be extended from and into the shaft 242, as shown in exemplarily shown FIGS. 3A-3E. However, the locations of the inlet 312 and outlet 314 are not limiting and can be within the conductive body 224 and/or the shaft 242. For example, one or more inlets and one or more outlets can also be used for branching the cooling channels into one or more cooling passages 310A, 310B, 310C, as exemplarily shown in FIGS. 3F. Accordingly, one embodiment of the invention provides a single point cooling control in the presence of multiple cooling passages by clustering the cooling passages into single inlet and single outlet. For example, branched cooling passages within the same inlet-outlet group can be controlled by a simple on/off control. In addition, the branched cooling passages can be grouped into two groups in mirror image as shown in the Figures. As a result, the design of these cooling passages provide better control over cooling fluid pressure, fluid flow rate, fluid resistance within the cooling structure. In one embodiment, cooling fluid can be flown within the cooling passages at controlled equal pressure, equal length, and/or equal resistance.

In another embodiment, the total length (L) for each of the cooling passages 310A, 310B, 310C is the same with each other, resulting in equal total length (L_{i=L}₂ . . . =L_{N}). In addition, one embodiment of the invention provides that cooling fluid flown inside the cooling passages 310A, 310B, 310C can be configured at equal flow rate. Accordingly, the structure and pattern of the one or more cooling passages 310A, 310B 310C, as exemplified in FIGS. 3A-3F, can provide equal distribution and equal resistance in delivering cooling fluid across the whole area of the substrate support surface 234 of the substrate support assembly 238.

The diameters of the cooling passage 310A, 310B, 310C are not limited and can be any suitable diameters, such as between about 1 mm to about 15 mm, e.g., about 9 mm. The structure of the cooling passages 310A, 310B, 310C may be, for example, grooves, channels, tongues, recesses, etc., distributed between the inner heating element 232B and the outer heating element 232A. The cooling passages 310A, 310B, 310C are contemplated to be positioned relatively near a hot area or hot zone of the conductive body 224 to improve overall temperature uniformity of the substrate support assembly.

As shown in FIG. 3F, in an alternate embodiment, cooling and/or heating of the substrate support surface to a desired temperature set point and regulating the temperature of the substrate can be provided by one or more cooling/heating channels embedded within the thermally conductive body. For example, a fluid can be desirably heated and/or cooled by a fluid recirculation unit and the heated/cooled fluid can be flown inside the one or more channels for heating and/or cooling the substrate support surface. In addition, the fluid recirculation unit can be located outside of the thermally conductive body and connected to the one or more channels to adjust the temperature of the fluid flown inside the one or more channels to the desired temperature set point.

In one embodiment, the fluid flown between the one or more channels and the fluid recirculation unit may be, for example, heated oil, heated water, cooled oil, cooled water, heated gas, cooled gas, and combinations thereof. The desired temperature set point may vary, and can be for example, a temperature of about 80° C. or larger, such as from about 100° C. to about 200° C.

In another embodiment, the fluid recirculation unit may include a temperature control unit provided to heat and/or cool the fluid and regulate the temperature of the fluid to the desired temperature set point. The fluid that is heated and/or cooled to the desired temperature set point in the temperature control unit can be re-circulated to the one or more channels embedded in the thermally conductive body of the substrate support assembly. In another embodiment, the one or more cooling/heating channels embedded within the thermally conductive body may be at various different or the same lengths to cover heating and/or cooling of the whole area of the substrate support surface. In still another embodiment, each of the one or more channels may further include two or more branched passages adapted to cover heating and cooling of the whole area of the substrate support surface.

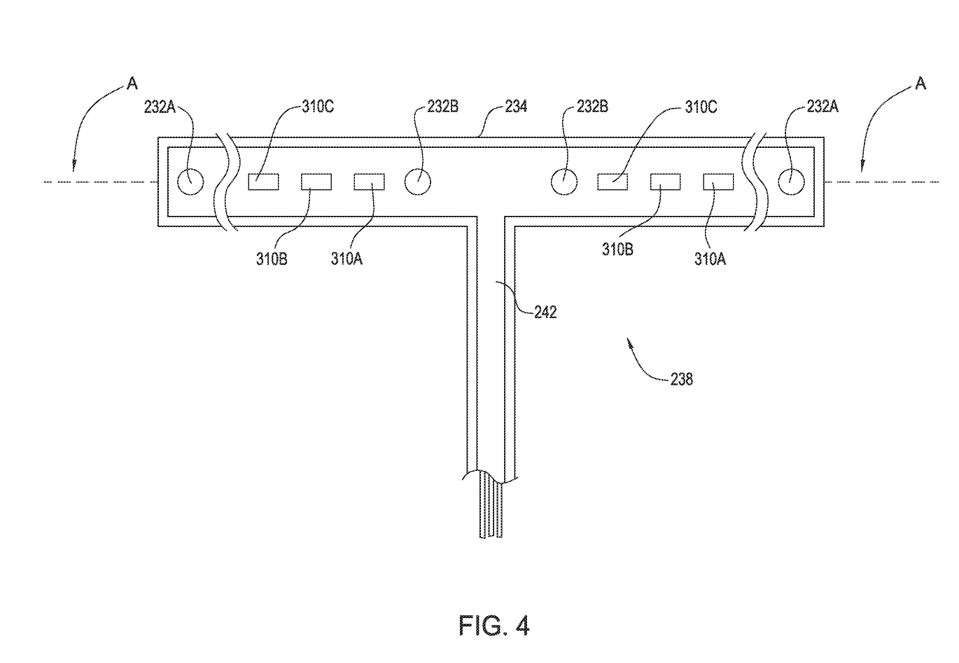

FIG. 4 provides one exemplary embodiment of a substrate support assembly having the cooling structure 310 and the heating element configured to be coplanar. For example, the cooling passages 310A, 310B, 310C may be adapted to be leveled, such as being formed about the vicinity of the same plane “A” with the heating element in order to maintain better temperature control during substrate processing.

The cooling passages 310A, 310B, 310C can be formed by techniques known in the art for forming channels and passages within a thermally conductive body. For example, the cooling structure 310 and/or the cooling passages 310A, 310B, 310C can be made by forging two conductive plates with grooves at corresponding positions together such that channels and passages are formed from matched grooves. The cooling channels and passages are sealed once they are formed within the conductive body to ensure better conductivity and prevent leaking of cooling fluids.

Other techniques for forming the heating elements, cooling channels and cooling passages, such as welding, forge welding, friction stir welding, explosive bonding, e-beam welding, and abrasion can also be used. Another embodiment of the invention provides that, during the manufacturing of the conductive body 224, two conductive plates with portions of grooves, recesses, channels, and passages on their surfaces are compressed or compacted together by isostatic compression such that heating elements, cooling channels and cooling passages can be formed in evenly compacted manner. In addition, loops, tubings, or channels for the one or more heating elements and the one or more cooling channels and cooling passages may be fabricated and bonded into the conductive body 224 of the substrate support assembly 238 using any known bonding techniques, such as welding, sand blasting, high pressure bonding, adhesive bonding, forging, among others.

The cooling structure 310 and the cooling passages 310A, 310B, 310C can be made of the same material, such as an aluminum material, as the conductive body 224. Alternatively, the cooling structure 310 and the cooling passages 310A, 310B, 310C can be made of a different material from the conductive body 224. For example, the cooling structure 310 and the cooling passages 310A, 310B, 310C can be made of a metal or metal alloy material which provides thermal conductivity. In another embodiment, the cooling structure 310 is made of a stainless steel material. However, other suitable materials or configurations can also be used.

Cooling fluid that can be flown into the cooling structure and/or cooling passages includes, but is not limited to, clean dry air, compressed air, gaseous materials, gases, water, coolants, liquids, cooling oil, and other suitable cooling gases or liquid materials. Preferably, gaseous materials are used. Suitable gaseous materials may include clean dry air, compressed air, filtered air, nitrogen gas, hydrogen gas, inert gas (e.g., argon gas, helium gas, etc.), and other gases. Flowing a gaseous material inside the one or more cooling channels and cooling passages is beneficial than flowing cooling water therein, even though cooling water can be used to advantage, since the gaseous material can provide cooling capability at a broader temperature range without the possibility of moisture leak to affect the quality of the deposited film on the processing substrate and chamber components. For example, cooling fluid, such as a gaseous material at a temperature of about 10° C. to about 25° C., can be used to flow into the one or more cooling channels and cooling passages and provide temperature cooling control from room temperature up to a high temperature of about 200° C. or higher, whereas cooling water generally operates at between about 20° C. to about 100° C.

In addition to the one or more power sources 374 coupled to the cooling structure 310 to regulate cooling of the substrate during substrate processing. Other controllers, such as fluid flow controllers can also be used to control and regulate the flow rates and/or pressure of different cooling fluids or gases into the cooling structure 310. Other flow control components may include one or more fluid flow injection valves. Further, cooling fluid flowing inside the cooling channels and cooling passages can be operated at a controlled flow rate to control cooling efficiency during substrate processing when the substrate is heated by the heating element and/or during chamber idle time. For example, for an exemplary cooling channel of about 9 mm in diameter, a pressure of about 25 psi to about 100 psi, such as about 50 psi, can be used to flow a gaseous cooling material. Thus, using the substrate support assembly 238 of the invention having the heating elements and the cooling structure, the temperature of the substrate can be kept constant and an uniform temperature distribution across the whole large surface area of the substrate is maintained.

The temperature of the conductive body 224 of the substrate support assembly 238 can be monitored by one or more thermocouples disposed in the conductive body 224 of the substrate support assembly 238. A axially-symmetric temperature distribution of a substrate above the conductive body 224 is generally observed with a temperature pattern which is characterized as substantially uniform for all points equidistant from a central axis perpendicular to the plane of the substrate support assembly 238, extending through the center of the substrate support assembly 238, and parallel to (and disposed within) the shaft 242 of the substrate support assembly 238.

### Maintaining the Temperature of the Substrate

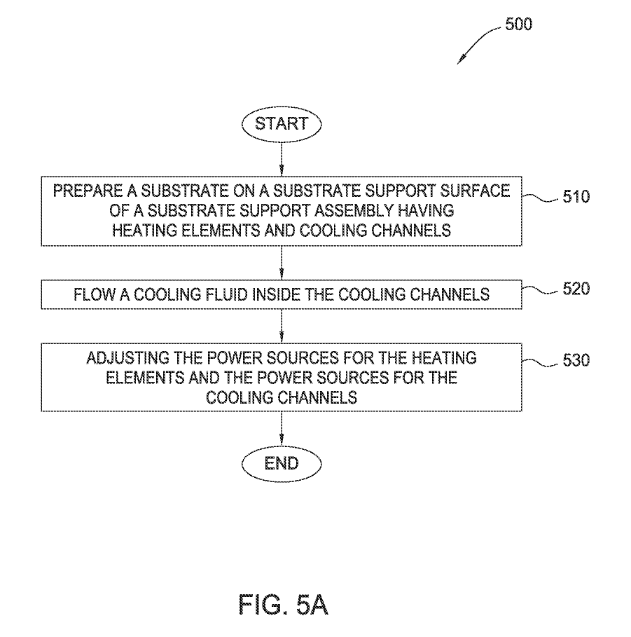

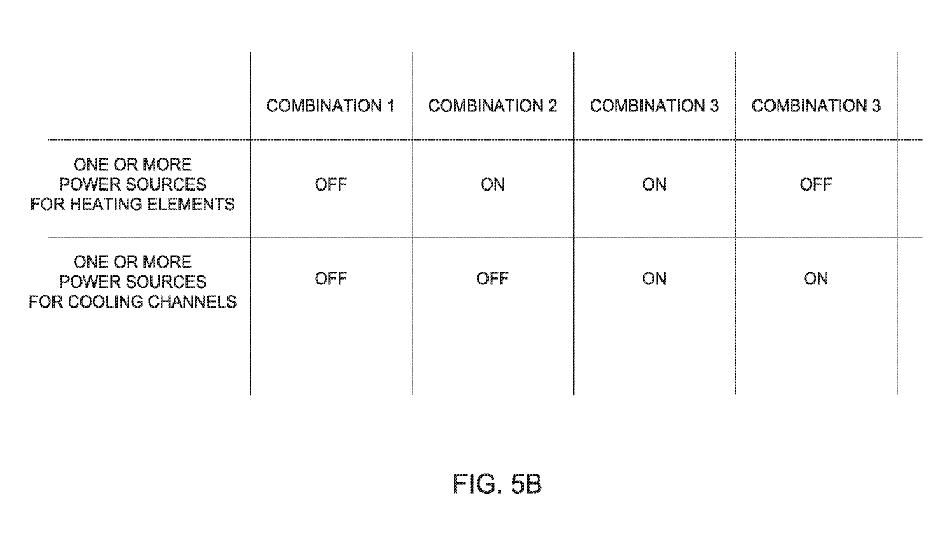

FIG. 5 is a flow diagram of one exemplary method 500 for controlling the temperature of a substrate within a process chamber. In operation, the substrate is positioned on a substrate support surface of a substrate support assembly inside the process chamber at step 510. Before and/or during substrate processing, the temperature of the substrate support surface on top of a conductive body of the substrate support assembly is kept at a set point temperature of about 400° C. or lower, such as between about 80° C. to about 400° C., or between about 100° C. to about 200° C. At step 520, a cooling fluid, gas or air is flown into the cooling channels of the cooling structure. For example, the cooling fluid can be flown at a constant flow rate into one or more cooling channels embedded in the conductive body of the substrate support assembly. In one embodiment, the cooling structure includes two or more equal length branched cooling passages and cooling fluid flown inside the length branched cooling passages can be maintained at a constant flow rate to cover cooling of the whole area of substrate support surface.

The temperature of the substrate can be maintained to various desired temperature set points and/or ranges, which may be required by a substrate processing regime. For example, during substrate processing, there may be different substrate processing temperature set points and for various desired durations.

At step 530, one embodiment of the invention provides that the power sources of the heating elements and the power sources of the cooling structure and/or cooling channels are adjusted such that the temperature of the substrate on the substrate support surface of the substrate support assembly can be maintained at desired temperature range for a desired duration. For example, the heating efficiency of the heating elements can be adjusted by adjusting the power of a power source connected to the heating elements. As another example, the cooling efficiency of the cooling structure elements can be adjusted by adjusting the power of a power source connected to the cooling structure and/or by adjusting the flow rate of cooling fluid flown therein. As another example, the power sources for the heating elements and the cooling channels can be adjusted by a combination of turning them on and/or off.

FIG. 5B illustrates various combinations to turn the power sources of the heating elements and the power sources of the cooling channels on and off for controlling the temperature of a substrate within a process chamber according to one embodiment of the invention. Each combination can be used to adjust and maintain the temperature of a substrate support surface of the substrate support assembly during substrate processing and/or non-processing time, such as when a plasma is induced, or any additional heat generated from the energy of the plasma is directed onto the substrate, in order to prevent any temperature spike or variation on the surface of the substrate.

For example, the cooling gas can be flown into the cooling channel by turning on the power source for flowing cooling fluid during substrate processing time and/or, alternatively at chamber idle time, non-processing time, or chamber cleaning/maintenance time. In addition, the power output of various power sources for the heating elements and cooling structure can be fine-tuned.

In one embodiment, the temperature of the substrate can be maintained to a constant process temperature of about 100° C. to about 200° C. across the entire surface of the substrate. As a result, one or more control loops may be need for software designs within the controller 290 for adjusting the heating and/or cooling efficiencies. In operation, one or more heating elements of the substrate support assembly can be set at a set point temperature of about 150° C. and a gaseous cooling material of clean dry air or compressed air having a temperature of about 16° C. or other suitable temperatures can be flown into the cooling channels at a constant flow rate to maintain the temperature of a substrate support surface of a substrate support assembly. When a plasma or an additional heat source is present inside the process chamber near the top of the substrate support surface, a constant flow of the cooling material using a pressure of about 50 psi is tested to maintained the temperature of the substrate support surface constantly at about 150° C. with a surface temperature uniformity of about +/−2° C. It is tested that the presence of an additional heat source even at about 300° C., will not affect the temperature of the substrate support surface such that the substrate support surface was tested to be kept constantly at about 150 ° C. by flowing the cooling fluid having an input temperature of about 16° C. inside the cooling channels of the invention. The cooling gas after cooling and after being flown out of the substrate support assembly is tested to be at an output temperature of about 120° C. Therefore, the cooling gas flowing inside the cooling channels of the invention exhibits a very efficient cooling effect, which is reflected by the difference of more than 100° C. between the output temperature and the input temperature of the cooling gas.

Table 1 illustrates one example of maintaining the temperature of a substrate support surface of a substrate support assembly having multiple power sources (to be turn on or off) equipped for igniting plasma and adjusting an outer heater, inner heater, and a cooling structure, respectively. The cooling structure may have multiple cooling passages (e.g., C₁, C₂, . . . C_{N}, branched from a single inlet-outlet group) to be controlled in the same group.

| | | | Process | Inner | Outer | | |
|---|---|---|---|---|---|---|---|
| | | Temperature | sub- | region | region | Temperature | |
| | Start | ramp up | strate | too hot | too hot | cool down | Idle |
| Heaterᵢₙₙₑᵣ | On | On | On | Off | On/Off | Off | Off |
| Heaterₒᵤₜₑᵣ | On | On | On | On/Off | Off | Off | Off |
| Cooling_{C1+C2+ . . . +Cn} | Off | On/Off | On/Off | On | On | On | Off |
| Plasma power | Off | On/Off | On | On/Off | On/Off | Off | Off |

The outer heater may be formed near the outer edges of the substrate support surface as possible in order to fight radiation loss. The inner heater may be useful for arriving at initial set point temperature. It is illustrative to show two heating elements. However, multiple heating elements can be used to control the temperature of the conductive body of the substrate support assembly. In addition, the inner heating element and the outer heating element may operate at different temperatures. In one embodiment, the outer heating element may be operated at a higher temperature than the set temperature of the inner heating element. When the outer heating element is operated at a higher temperature, there may be a hot area near the outer heating element and power source coupled to the cooling structure can be turned on to flow in cooling fluid. A substantially uniform temperature distribution is thus produced across the substrate in this fashion.

Accordingly, the one or more heating elements and the one or more cooling channels and cooling passages are disposed in the substrate support assembly to maintain the substrate support surface at a uniform temperature of 400° C. or lower, such as between about 100° C. to about 200° C. For example, the heating efficiency of the heating element can be adjusted by the power source 274 and the cooling efficiency of the cooling structure can be adjusted by the power source 374 and/or the flow rate of the cooling fluid flown therein, such as in a two-way heating-cooling temperature control.

As a result, the substrate support assembly and the substrate positioned thereon is controllably maintained at a desired set point temperature. Using the substrate support assembly of the invention, a temperature uniformity of about +/−5° C. or less at the set point temperature can be observed for the conductive body 224 of the substrate support assembly 238. Even after multiple substrates have been processed by the process chamber, a process set point temperature repeatability of about +/−2° C. or less can be observed. In one embodiment, the temperature of the substrate can be kept constant, having a normalized temperature variation of about +/−10° C. temperature, such as about +/−5° C. temperature variation.

In addition, a base support plate may be positioned below the conductive body to provide structural support to the substrate support assembly and the substrate thereon to prevent them from deflecting due to gravity and high temperature and to ensure relatively uniform and repeatable contact between the conductive body and the substrate. Accordingly, the conductive body in the substrate support assembly 238 of the invention provides a simple design with heating and cooling capability to control the temperature of the large area substrate.

In one embodiment, the substrate support assembly 238 is adapted to process a rectangular substrate. The surface area of a rectangular substrate for flat panel display is typically large, for example, a rectangle of about 300 mm by about 400 mm or larger, e.g., about 370 mm by about 470 mm or larger. The dimensions of the process chamber 202, the conductive body 224, and related components of the process chamber 202 are not limited and generally are proportionally larger than the size and dimension of the substrate 240 to be processed in the process chamber 202. For example, when processing a large area square substrate having a width of about 370 mm to about 2160 mm and a length of about 470 mm to about 2460 mm, the conductive body may include a width of about 430 mm to about 2300 mm and a length of about 520 mm to about 2600 mm, whereas the process chamber 202 may include a width of about 570 mm to about 2360 mm and a length of about 570 mm to about 2660 mm. As another example, the substrate support surface may have a dimension of about 370 mm by about 470 mm or larger.

For flat panel display application, the substrate may comprise a material that is essentially optically transparent in the visible spectrum, for example glass or clear plastic. For example, for thin film transistor applications, the substrate may be a large area glass substrate having a high degree of optical transparency. However, the invention is equally applicable to substrate processing of any types and sizes. Substrates of the invention can be circular, square, rectangular, or polygonal for flat panel display manufacturing. In addition, the invention applies to substrates for fabricating any devices, such as flat panel display (FPD), flexible display, organic light emitting diode (OLED) displays, flexible organic light emitting diode (FOLED) display, polymer light emitting diode (PLED) display, liquid crystal displays (LCD), organic thin film transistor, active matrix, passive matrix, top emission device, bottom emission device, solar cell, solar panel, etc., and can be on any of the silicon wafers, glass substrates, metal substrates, plastic films (e.g., polyethylene terephthalate (PET), polyethylene naphthalate (PEN), etc.), plastic epoxy films, among others. The invention is especially suitable for a low temperature PECVD process, such as those techniques used for fabricating a flexible display device, where temperature cooling control during substrate processing is desired.

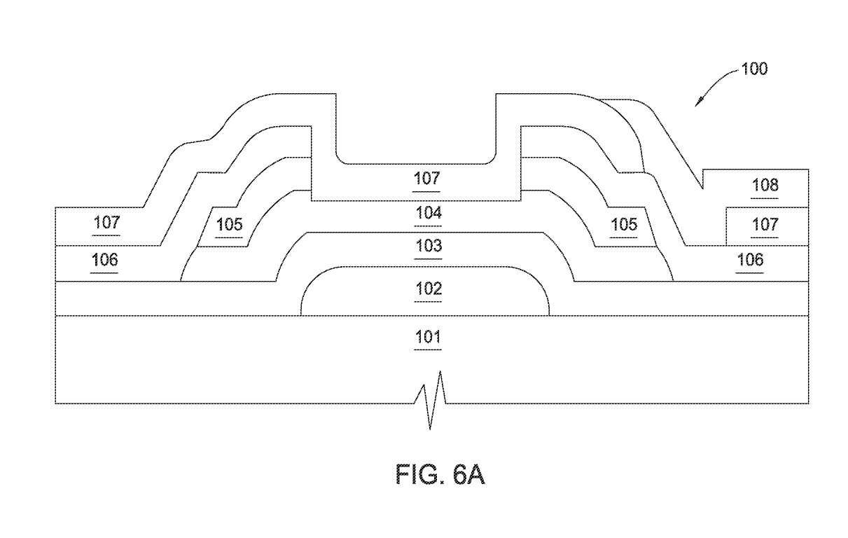

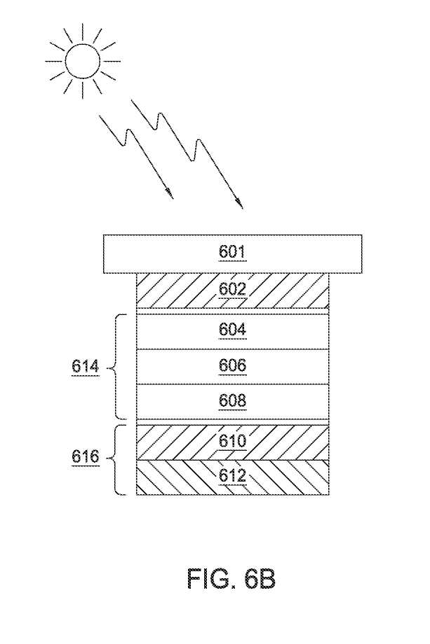

FIG. 6A illustrates a cross-sectional schematic view of a thin film transistor (TFT) structure that can be fabricated on a substrate as described herein. A common TFT structure is the back channel etch (BCE) inverted staggered (or bottom gate) TFT structure. The BCE process may provide the deposition of gate dielectric silicon nitride (SiN), and the intrinsic as well as n+ doped amorphous silicon films on a substrate, e.g., optionally in the same PECVD pump-down run. A substrate 101 may comprise a material that is essentially optically transparent in the visible spectrum, such as, for example, glass or clear plastic. The substrate 101 may be of varying shapes or dimensions. Typically, for TFT applications, the substrate is a glass substrate with a surface area greater than about 500 mm².

A gate electrode layer 102 is formed on the substrate 101. The gate electrode layer 102 comprises an electrically conductive layer that controls the movement of charge carriers within the TFT. The gate electrode layer 102 may comprise a metal such as, for example, aluminum (Al), tungsten (W), chromium (Cr), tantalum (Ta), or combinations thereof, among others. The gate electrode layer 102 may be formed using conventional deposition, lithography and etching techniques. Between the substrate 101 and the gate electrode layer 102, there may be an optional insulating material, for example, such as silicon dioxide (SiO₂) or silicon nitride (SiN), which may also be formed using an embodiment of a PECVD system described herein. The gate electrode layer 102 is then lithographically patterned and etched using conventional techniques to define the gate electrode.

A gate dielectric layer 103 is formed on the gate electrode layer 102. The gate dielectric layer 103 may be silicon dioxide (SiO₂), silicon oxynitride (SiON), or silicon nitride (SiN), deposited using an embodiment of a PECVD system according to this invention. The gate dielectric layer 103 may be formed to a thickness in the range of about 100 Å to about 6000 Å.

A semiconductor layer 104 is formed on the gate dielectric layer 103. The semiconductor layer 104 may comprise polycrystalline silicon (polysilicon) or amorphous silicon (α-Si), which could be deposited using an embodiment of a PECVD system incorporating in this invention or other conventional methods known to the art. The semiconductor layer 104 may be deposited to a thickness in the range of about 100 Å to about 3000 Å.

A doped semiconductor layer 105 is formed on top of the semiconductor layer 104. The doped semiconductor layer 105 may comprise n-type (n+) or p-type (p+) doped polycrystalline (polysilicon) or amorphous silicon (α-Si), which could be deposited using an embodiment of a PECVD system incorporating in this invention or other conventional methods known to the art. Doped semiconductor layer 105 may be deposited to a thickness within a range of about 100 Å to about 3000 Å. An example of the doped semiconductor layer 105 is n+ doped α-Si film. The semiconductor layer 104 and the doped semiconductor layer 105 are lithographically patterned and etched using conventional techniques to define a mesa of these two films over the gate dielectric insulator, which also serves as storage capacitor dielectric. The doped semiconductor layer 105 directly contacts portions of the semiconductor layer 104, forming a semiconductor junction.

A conductive layer 106 is then deposited on the exposed surface. The conductive layer 106 may comprise a metal such as, for example, aluminum (Al), tungsten (W), molybdenum (Mo), chromium (Cr), tantalum (Ta), and combinations thereof, among others. The conductive layer 106 may be formed using conventional deposition techniques. Both the conductive layer 106 and the doped semiconductor layer 105 may be lithographically patterned to define source and drain contacts of the TFT.

Afterwards, a passivation layer 107 may be deposited. The passivation layer 107 conformably coats exposed surfaces. The passivation layer 107 is generally an insulator and may comprise, for example, silicon dioxide (SiO₂) or silicon nitride (SiN). The passivation layer 107 may be formed using, for example, PECVD or other conventional methods known to the art. The passivation layer 107 may be deposited to a thickness in the range of about 1000 Å to about 5000 ÅA. The passivation layer 107 is then lithographically patterned and etched using conventional techniques to open contact holes in the passivation layer.

A transparent conductor layer 108 is then deposited and patterned to make contacts with the conductive layer 106. The transparent conductor layer 108 comprises a material that is essentially optically transparent in the visible spectrum and is electrically conductive. Transparent conductor layer 108 may comprise, for example, indium tin oxide (ITO) or zinc oxide, among others. Patterning of the transparent conductive layer 108 is accomplished by conventional lithographical and etching techniques. The doped or un-doped (intrinsic) amorphous silicon (α-Si), silicon dioxide (SiO2), silicon oxynitride (SiON) and silicon nitride (SiN) films used in liquid crystal displays (or flat panels) could all be deposited using an embodiment of a plasma enhanced chemical vapor deposition (PECVD) system incorporating in this invention.

FIG. 6B depicts an exemplary cross sectional view of a silicon-based thin film solar cell 600 that can be fabricated on a substrate as described herein in accordance with one embodiment of the invention. A substrate 601 can be used and may comprise a material that is essentially optically transparent in the visible spectrum, such as, for example, glass or clear plastic. The substrate 601 may be of varying shapes or dimensions. The substrate 601 may be thin sheet of metal, plastic, organic material, silicon, glass, quartz, or polymer, among others suitable materials. The substrate 601 may have a surface area greater than about 1 square meters, such as greater than about 500 mm². For example, the substrate 601 suitable for solar cell fabrication may be a glass substrate with a surface area greater than about 2 square meters.

A transmitting conducting oxide layer 602, as shown in FIG. 6B, can be deposited on the substrate 601. An optional dielectric layer (not shown) may be disposed between the substrate 601 and the transmitting conducting oxide layer 602. For example, the optional dielectric layer may be a SiON or silicon oxide (SiO₂) layer. The transmitting conducting oxide layer 602 may include, but not limited to, at least one oxide layer selected from a group consisting of tin oxide (SnO₂), indium tin oxide (ITO), zinc oxide (ZnO), or the combination thereof. The transmitting conducting oxide layer 602 may be deposited by a CVD process as described herein, a PVD process, or other suitable deposition process. For example, the transmitting conducting oxide layer 602 may be deposited by a reactive sputter depositing process having predetermined film properties. The substrate temperature is controlled between about 150 degrees Celsius and about 350 degrees Celsius. Detail process and film property requirements are disclosed in detail by U.S. patent application Ser. No. 11/614,461, filed Dec. 21, 2006 by Li et al, title “Reactive Sputter Deposition of a Transparent Conductive Film”, and is herein incorporated by reference.

A photoelectric conversion unit 614 can be formed on a surface of the substrate 601. The photoelectric conversion unit 614 typically includes a p-type semiconductor layer 604, a n-type semiconductor layer 608, and an intrinsic type (i-type) semiconductor layer 606 as a photoelectric conversion layer. The p-type semiconductor layer 604, n-type semiconductor layer 608, and intrinsic type (i-type) semiconductor layer 606 may be comprised of a material, such as amorphous silicon (α-Si), polycrystalline silicon (poly-Si), and microcrystalline silicon (pc-Si) at a thickness of between about 5 nm and about 50 nm.

In one embodiment, the p-type semiconductor layer 604, intrinsic type (i-type) semiconductor layer 606, and n-type semiconductor layer 608 may be deposited by the method and apparatus as described herein. The substrate temperature during the deposition process is maintained at a predetermined range. In one embodiment, the substrate temperature is maintained at less than about 450 degrees Celsius so as to allow the substrates with low melt point, such as alkaline glasses, plastic and metal, to be utilized. In another embodiment, the substrate temperature in the process chamber is maintained at a range between about 100 degrees Celsius to about 450 degrees Celsius. In yet another embodiment, the substrate temperature is maintained at a range about 150 degrees Celsius to about 400 degrees Celsius, such as 350 degrees Celsius.

During processing, a gas mixture is flowed into the process chamber and used to form a RF plasma and deposit, for example, a p-type microcrystalline silicon layer. In one embodiment, the gas mixture includes a silane-based gas, a group III doping gas and a hydrogen gas (H₂). Suitable examples of the silane-based gas include, but not limited to, mono-silane (SiH₄), di-silane(Si₂H₆), silicon tetrafluoride (SiF₄), silicon tetrachloride(SiCl₄), and dichlorosilane (SiH₂Cl₂), and the like. The group III doping gas may be a boron containing gas selected from a group consisting of trimethylborate (TMB), diborane (B₂H₆), BF₃, B(C₂H₅)₃, BH₃, and B(CH₃)₃. The supplied gas ratio among the silane-based gas, group III doping gas, and H₂ gas is maintained to control reaction behavior of the gas mixture, thereby allowing a desired proportion of the crystallization and dopant concentration to be formed in the p-type microcrystalline silicon layer. In one embodiment, the silane-based gas is SiH₄ and the group III doping gas is B(CH₃)₃. SiH₄ gas may be 1 sccm/L and about 20 sccm/L. H₂ gas may be provided at a flow rate between about 5 sccm/L and 500 sccm/L. B(CH₃)₃ may be provided at a flow rate between about 0.001 sccm/L and about 0.05 sccm/L. The process pressure is maintained at between about 1 Torr to about 20 Torr, for example, such as greater than about 3 Torr. A RF power between about 15 milliWatts/cm² and about 200 milliWatts/cm² may be provided to the showerhead.

One or more inert gases may be optionally included with the gas mixture provided to the process chamber 202. The inert gas may include, but not limited to, noble gas, such as Ar, He, Xe, and the like. The inert gas may be supplied to the process chamber 202 at a flow ratio between about 0 sccm/L and about 200 sccm/L. The processing spacing for a substrate having an upper surface area greater than 1 square meters is controlled between about 400 mils and about 1200 mils, for example, between about 400 mils and about 800 mils, such as 500 mils.

The i-type semiconductor layer 606 can be a non-doped silicon based film deposited under controlled process condition to provide film properties having improved photoelectric conversion efficiency. In one embodiment, the i-type semiconductor layer can be comprised of i-type polycrystalline silicon (poly-Si), i-type microcrystalline silicon (μc-Si), or i-type amorphous silicon film (a-Si). In one embodiment, substrate temperature for depositing, for example, an i-type amorphous silicon film is maintained at less than about 400 degrees Celsius, such as at a range about 150 degrees Celsius to about 400 degrees Celsius, such as 200 degrees Celsius. Detail process and film property requirements are disclosed in detail by U.S. patent application Ser. No. 11/426,127, filed Jun. 23, 2006, which published as United States Patent Publication Number 2007/0298590 on Dec. 27, 2007, and is herein incorporated by reference. The i-type amorphous silicon film may be deposited using the method and apparatus as described herein, for example, by supplying a gas mixture of hydrogen gas to silane gas in a ratio of about 20:1 or less. Silane gas may be provided at a flow rate between about 0.5 sccm/L and about 7 sccm/L. Hydrogen gas may be provided at a flow rate between about 5 sccm/L and 60 sccm/L. A RF power between 15 milliWatts/cm² and about 250 milliWatts/cm² may be provided to the showerhead. The pressure of the chamber may be maintained between about 0.1 Torr and 20 Torr, such as between about 0.5 Torr and about 5 Torr. The deposition rate of an intrinsic type amorphous silicon layer may be about 100 Å/min or more.

The n-type semiconductor layer 608 can be, for example, an amorphous silicon layer, deposited at the same or different process chamber as the i-type and n-type semiconductor layers. For example, a group V element can be selected to be doped into a semiconductor layer into a n-type layer. In one embodiment, the n-type semiconductor layer 608 may be fabricated by an amorphous silicon film (α-Si), a polycrystalline film (poly-Si), and a microcrystalline film (pc-Si) with a thickness between around 5 nm and about 50 nm. For example, the n-type semiconductor layer 608 may be comprised of phosphorous doped amorphous silicon.

During processing, a gas mixture is flowed into the process chamber and used to form a RF plasma and deposit the n-type amorphous silicon layer 608. In one embodiment, the gas mixture includes a silane-based gas, a group V doping gas and a hydrogen gas (H₂). Suitable examples of the silane-based gas include, but not limited to, mono-silane (SiH₄), di-silane(Si₂H₆), silicon tetrafluoride (SiF₄), silicon tetrachloride(SiCl₄), and dichlorosilane (SiH₂Cl₂), and the like. The group V doping gas may be a phosphorus containing gas selected from a group consisting of PH₃, P₂H₅, PO₃, PF₃, PF₅, and PCl₃. The supplied gas ratio among the silane-based gas, Group V doping gas, and H₂ gas is maintained to control reaction behavior of the gas mixture, thereby allowing a desired dopant concentration to be formed in the n-type amorphous layer 608. In one embodiment, the silane-based gas is SiH₄ and the Group V doping gas is PH₃. SiH₄ gas may be provided at a flow rate between about 1 sccm/L and about 10 sccm/L. H₂ gas may be provided at a flow rate between about 4 sccm/L and about 50 sccm/L. PH₃ may be provided at a flow rate between about 0.0005 sccm/L and about 0.0075 sccm/L. In other words, if phosphine is provided in a 0.5% molar or volume concentration in a carrier gas, such as H₂ gas, then the dopant/carrier gas mixture may be provided at a flow rate between about 0.1 sccm/L and about 1.5 sccm/L. A RF power between about 15 milliWatts/cm² and about 250 milliWatts/cm² may be provided to the showerhead. The pressure of the chamber may be maintained between about 0.1 Torr and 20 Torr, preferably between about 0.5 Torr and about 4 Torr. The deposition rate of the n-type amorphous silicon buffer layer may be about 200 Å/min or more.

Optionally, one or more inert gases may be included with the gas mixture provided to the process chamber 202. The inert gas may include, but not limited to, noble gas, such as Ar, He, Xe, and the like. The inert gas may be supplied to the process chamber 202 at a flow ratio between about 0 sccm/L and about 200 sccm/L. In one embodiment, the processing spacing for a substrate having an upper surface area greater than 1 square meters is controlled between about 400 mils and about 1200 mils, for example, between about 400 mils and about 800 mils, such as 500 mils.

In one embodiment, the substrate temperature controlled for depositing a n-type amorphous layer is controlled at a temperature lower than the temperature for depositing the p-type amorphous layer and i-type amorphous layer. As the i-type amorphous layer has been deposited on the substrate with a desired crystalline volume and film property, a relatively lower process temperature is performed to deposit the n-type amorphous layer to prevent the underlying silicon layers from thermal damage and grain reconstruction. In one embodiment, the substrate temperature is controlled at a temperature lower than about 350 degree Celsius. In another embodiment, the substrate temperature is controlled at a temperature between about 100 degree Celsius and about 300 degree Celsius, such as between about 150 degree Celsius and about 250 degree Celsius, for example, about 200 degree Celsius.

A backside electrode 616 may be disposed on the photoelectric conversion unit 614. In one embodiment, the backside electrode 616 may be formed by a stacked film that includes a transmitting conducting oxide layer 610 and a conductive layer 612. The transmitting conducting oxide layer 610 may be fabricated from a material similar as the transmitting conducting oxide layer 602. Suitable material for the transmitting conducting oxide layer 610 include, but is not limited to, tin oxide (SnO₂), indium tin oxide (ITO), zinc oxide (ZnO), or the combination thereof. The conductive layer 612 may include a metal material, including, but not limited to, Ti, Cr, Al, Ag, Au, Cu, Pt, and combinations and alloys thereof. The transmitting conducting oxide layer 610 and the conductive layer 612 may be deposited by a CVD process, a PVD process, or other suitable deposition process.

As the transmitting conducting oxide layer 610 is deposited on the photoelectric conversion unit 614, a relatively low process temperature is utilized to prevent the silicon-containing layers in the photoelectric conversion unit 614 from thermal damage and undesired grain reconstruction. In one embodiment, the substrate temperature is controlled between about 150 degrees Celsius and about 300 degrees Celsius, such as between about 200 degrees Celsius and about 250 degrees Celsius. Alternatively, fabrication for photovoltaic devices or solar cells as described herein may be deposited in a reversed order. For example, the backside electrode 616 may be disposed initially on the substrate 601 before forming the photoelectric conversion unit 614.

Although the embodiment of FIG. 6B depicts a single junction photoelectric conversion unit formed on the substrate 601, a different number of photoelectric conversion units, e.g., more than one, may be formed on the photoelectric conversion unit 614 to meet different process requirements and device performance.

In operation, light can be provided by the environment, e.g., sunlight or other photons, to the solar cell and the photoelectric conversion unit 614 may absorb the photo-energy and converts the energy into electrical energy through the p-i-n junctions formed in the photoelectric conversion unit 614, thereby generating electricity or energy.

Although several preferred embodiments which incorporate the teachings of the present invention have been shown and described in detail, those skilled in the art can readily devise many other varied embodiments that still incorporate these teachings. In addition, while the foregoing is directed to embodiments of the present invention, other and further embodiments of the invention may be devised without departing from the basic scope thereof, and the scope thereof is determined by the claims that follow.

1. A substrate support assembly adapted to support a large area substrate inside a process chamber, comprising:
a thermally conductive body having a rectangular shape and a substrate support surface, the thermally conductive body having a first half and a second half that are mirror images, each half of the thermally conductive body having a cooling channel embedded within the thermally conductive body, wherein the cooling channel has:
two or more branched passages, wherein the two or more branched passages are of different patterns and equal length and are configured to provide substantially equal distribution and substantially equal resistance in delivering cooling fluid across the entire substrate support surface;
a single inlet; and
a single outlet, wherein all the branched passages are coupled between the single inlet and the single outlet; and
one or more heating elements embedded in the thermally conductive body, wherein the one or more heating elements are positioned coplanar with the cooling channel.

2. The substrate support assembly of claim 1, wherein the one or more heating elements comprises, in each half of the thermally conductive body:
an inner heating element embedded within the thermally conductive body, the inner heating element having a first length and a first pattern; and
an outer heating element embedded within the thermally conductive body, the outer heating element having a second length that is different than the first length and a second pattern that is different than the first pattern, wherein the cooling channel is disposed between the inner heating element and the outer heating element, and the cooling channel is positioned substantially coplanar with the inner and outer heating elements.

3. The substrate support assembly of claim 2, wherein the thermally conductive body comprises an aluminum material.

4. The substrate support assembly of claim 3, further comprising a fluid recirculation unit connected to the cooling channel and located outside of the thermally conductive body.

5. The substrate support assembly of claim 4, wherein the cooling channel has at least one portion that is substantially parallel to a side of the thermally conductive body.

6. The substrate support assembly of claim 5, wherein the two or more branched passages has three branched passages.

7. The substrate support assembly of claim 1, further comprising a shaft coupled to the thermally conductive body, wherein the shaft has a conduit, and the single inlet and the single outlet are extended from and into the shaft.

8. The substrate support assembly of claim 7, further comprising:
a fluid recirculation unit connected to the cooling channel and located outside of the thermally conductive body; and
an on/off control coupled to the single inlet or the single outlet to control the two or more branched passages.

9. The substrate support assembly of claim 1, wherein the cooling channel has at least one portion that is substantially parallel to a side of the thermally conductive body.

10. The substrate support assembly of claim 1, wherein the two or more branched passages has three branched passages.

11. A substrate support assembly adapted to support a large area substrate inside a process chamber, comprising:
a thermally conductive body having a rectangular shape and a substrate support surface, the thermally conductive body having a first half and a second half that are mirror images, each half of the thermally conductive body having:
an inner heating element embedded within the thermally conductive body;
an outer heating element embedded within the thermally conductive body; and
a cooling channel embedded within the thermally conductive body between the inner heating element and the outer heating element, wherein the cooling channel has:
two or more branched passages, wherein the two or more branched passages are of different patterns and equal length and are configured to provide substantially equal distribution and substantially equal resistance in delivering cooling fluid across the entire substrate support surface;
a single inlet; and
a single outlet, wherein all the branched passages are coupled between the single inlet and the single outlet.

12. The substrate support of claim 11, further comprising a shaft coupled to the thermally conductive body, wherein the shaft has a conduit, and the single inlet and the single outlet are extended from and into the shaft.

13. An apparatus for processing a large area substrate, comprising:
a process chamber;
a substrate support assembly, comprising:
a thermally conductive body having a rectangular shape and a substrate support surface, the thermally conductive body having a first half and a second half that are mirror images, each half of the thermally conductive body having a cooling channel embedded within the thermally conductive body, wherein the cooling channel has:
two or more branched passages, wherein the two or more branched passages are of different patterns and equal length and are configured to provide substantially equal distribution and substantially equal resistance in delivering cooling fluid across the entire substrate support surface;
a single inlet; and
a single outlet, wherein all of the two or more branched passages are coupled between the single inlet and a single outlet; and
a gas distribution plate assembly disposed in the process chamber to deliver one or more process gases above the substrate support assembly.

14. The apparatus of claim 13, wherein the thermally conductive body further comprises:
an inner heating element embedded within the thermally conductive body, the inner heating element having a first length and a first pattern; and
an outer heating element embedded within the thermally conductive body, the outer heating element having a second length that is different than the first length and a second pattern that is different than the first pattern, wherein the cooling channel is between the inner heating element and the outer heating element and positioned substantially coplanar with the inner and outer heating elements.

15. The apparatus of claim 14, wherein the thermally conductive body comprises an aluminum material.

16. The apparatus of claim 15, further comprising a fluid recirculation unit connected to the cooling channel and located outside of the thermally conductive body.

17. The apparatus of claim 16, wherein the cooling channel has at least one portion that is substantially parallel to a side of the thermally conductive body.

18. The apparatus of claim 17, wherein the two or more branched passages has three branched passages.

19. The apparatus of claim 18, wherein the inner heating element and the outer heating element are positioned in a substantially symmetrical pattern within the body.

20. The apparatus of claim 13, wherein the substrate support assembly further comprises a shaft coupled to the thermally conductive body, the shaft has a conduit, and the single inlet and the single outlet are extended from and into the shaft.
